(19) United States
(12) Patent Application Publication
(10) Pub. No.: US 2024/0266481 A1
(43) Pub. Date: Aug. 8, 2024

(54) ULTRAVIOLET LED DEVICE AND PREPARATION METHOD THEREFOR

(71) Applicant: FOSHAN NATIONSTAR OPTOELECTRONICS CO., LTD., Foshan (CN)

(72) Inventors: Yurong LI, Foshan (CN); Mingjun ZHU, Foshan (CN); Haojie GUO, Foshan (CN); Yan CHEN, Foshan (CN); Zishan LU, Foshan (CN); Danwei LI, Foshan (CN)

(73) Assignee: FOSHAN NATIONSTAR OPTOELECTRONICS CO., LTD., Foshan, GD (CN)

(21) Appl. No.: 18/564,352

(22) PCT Filed: Aug. 27, 2021
(86) PCT No.: PCT/CN2021/115041

§ 371 Date: Nov. 27, 2023

(30) Foreign Application Priority Data
May 25, 2021 (CN) 202110573999.9

(51) Int. Cl. H01L 33/56; H01L 33/00; H01L 33/44; H01L 33/48; H01L 33/58

(52) U.S. Cl. CPC H01L 33/56; H01L 33/0095; H01L 33/44; H01L 33/486; H01L 33/58; H01L 2933/0025; H01L 2933/005; H01L 2933/0058

(57) ABSTRACT

An ultraviolet LED device includes a holder and a lens. The holder is provided with an accommodation cavity. The lens is configured to seal the accommodation cavity. A chip is disposed at a cavity bottom of the accommodation cavity. The accommodation cavity is filled with a Si—O main chain polymer. The holder is provided with at least one through hole. The at least one through hole is located at the bottom of the holder and communicates with the accommodation cavity. A sealing member is disposed in each of the at least one through hole.

### CROSS-REFERENCE TO RELATED APPLICATION(S)

This is a national stage application filed under 37 U.S.C. 371 based on International Patent Application No. PCT/CN2021/115041, filed Aug. 27, 2021, which claims priority to Chinese Patent Application No. 202110573999.9 filed with the China National Intellectual Property Administration (CNIPA) on May 25, 2021, the disclosure of which is incorporated herein by reference in its entirety.

### TECHNICAL FIELD

The present application relates to the field of light-emitting diode (LED) technologies, for example, an ultraviolet light-emitting diode device (LED) and a preparation method therefor.

### BACKGROUND

There are two mainstream encapsulation modes for an ultraviolet LED device. One is to encapsulate a cupped ceramic substrate with quartz glass. The other one is to encapsulate a cupped ceramic substrate with silicone resin. In the first encapsulation mode, the chip and the quartz glass are filled with air or vacuumed therebetween, so a relatively high proportion of ultraviolet (UV) energy cannot be emitted through the air and quartz glass, resulting in a relatively low light output efficiency of an encapsulation device. In the second encapsulation mode, although the radiant power of the device can be greatly improved in the initial stage, silicone resin is a thermosetting polysiloxane polymer with a highly cross-linked structure, and its UV resistance is poor. UV irradiation accelerates the destruction of molecular structures of the silicone resin, causes the cracking and discoloration of the silicone resin and causes problems such as a relatively poor air tightness and low service life of the ultraviolet LED device.

### SUMMARY

The present application provides an ultraviolet LED device that has a relatively high light output efficiency and a relatively long service life.

The present application further provides a method for preparing an ultraviolet LED device, which has a relatively high production efficiency.

An ultraviolet LED device is provided and includes a holder and a lens. The holder is provided with an accommodation cavity, the lens is configured to seal the accommodation cavity, a chip is disposed at a cavity bottom of the accommodation cavity, the accommodation cavity is filled with a silicon-oxygen (Si—O) main chain polymer, the holder is provided with at least one through hole, the at least one through hole is located at a bottom of the holder and communicates with the accommodation cavity, the at least one through hole and the chip are spaced apart, and a sealing member is disposed in each of the at least one through hole.

As a solution of the ultraviolet LED device, two through holes are spaced apart at the bottom of the holder.

As a solution of the ultraviolet LED device, the sealing member includes a metal material, or the sealing member is made of resin.

As a solution of the ultraviolet LED device, the sealing member is a silver paste member.

As a solution of the ultraviolet LED device, one side of the chip facing the lens is provided with a protective layer, and the protective layer is configured to isolate the chip from the Si—O main chain polymer.

As a solution of the ultraviolet LED device, the protective layer is made of fluororesin.

As a solution of the ultraviolet LED device, one side of the protective layer facing the lens is a cambered surface or spherical surface, and the cambered surface or spherical surface protrudes towards one side of the lens.

As a solution of the ultraviolet LED device, the at least one through hole and the protective layer are spaced apart.

As a solution of the ultraviolet LED device, the holder includes a substrate and an annular box dam, the lens is connected to the box dam, the accommodation cavity is formed between the substrate, the box dam and the lens, the chip is secured on the substrate, a surface of one side of the substrate facing away from the accommodation cavity is provided with pins, the at least one through hole is disposed on the substrate, and the at least one through hole penetrates through the pins.

As a solution of the ultraviolet LED device, the holder includes a substrate and an annular box dam, the lens is connected to the box dam, the accommodation cavity is formed between the substrate, the box dam and the lens, the chip is secured on the substrate, the at least one through hole is disposed on the substrate, a surface of one side of the substrate facing away from the accommodation cavity is provided with pins, and the at least one through hole and the pins are spaced apart.

A method for preparing an ultraviolet LED device is further provided for preparing the preceding ultraviolet LED device and includes the steps below.

The bottom of the holder is machined through a drilling tool to form the at least one through hole, where the at least one through hole communicates with the accommodation cavity on the holder.

The chip is soldered onto the cavity bottom of the accommodation cavity.

The lens is secured on the soldered holder, where the lens is configured to seal the accommodation cavity.

The secured holder is inverted to enable the at least one through hole to face upward, and the accommodation cavity is filled with the Si—O main chain polymer through the at least one through hole.

The each of the at least one through hole is sealed by the sealing member after filling with the Si—O main chain polymer is completed.

As a solution of the method for preparing an ultraviolet LED device, before the lens is secured on the soldered holder, the method further includes the step below.

The protective layer is coated on a surface of the chip.

As a solution of the method for preparing an ultraviolet LED device, the sealing member is a silver paste member, and that the each of the at least one through hole is sealed by the sealing member includes the step below.

The each of the at least one through hole is filled with silver paste, and after filling with the silver paste is completed, a high-temperature treatment is performed on the each of the at least one through hole to harden the silver paste to form the silver paste member.

As a solution of the method for preparing an ultraviolet LED device, two through holes are disposed at the bottom of the holder, and that the accommodation cavity is filled with the Si—O main chain polymer through the at least one through hole, and the each of the at least one through hole is sealed by the sealing member after filling with the Si—O main chain polymer is completed includes the step below.

The accommodation cavity is filled with the Si—O main chain polymer through one of the two through holes, another one of the two through holes is used as an air outlet, and when the Si—O main chain polymer overflows or is about to overflow from the another one of the two through holes which is used as the air outlet, filling with the Si—O main chain polymer is stopped, and the two through holes are respectively sealed by two sealing members.

### BRIEF DESCRIPTION OF DRAWINGS

FIG. 1 is a diagram of an ultraviolet LED device according to an embodiment of the present application.

FIG. 2 is a diagram of another ultraviolet LED device according to an embodiment of the present application.

FIG. 3 is a diagram of another ultraviolet LED device according to an embodiment of the present application.

FIG. 4 is a diagram of another ultraviolet LED device according to an embodiment of the present application.

FIG. 5 is a top view of a holder according to an embodiment of the present application.

FIG. 6 is a top view of another holder according to an embodiment of the present application.

FIG. 7 is a bottom view of a holder according to an embodiment of the present application.

FIG. 8 is a bottom view of another holder according to an embodiment of the present application.

FIG. 9 is a bottom view of another holder according to an embodiment of the present application.

FIG. 10 is a bottom view of another holder according to an embodiment of the present application.

### REFERENCE LIST

1 lens
2 box dam
3 substrate
301 pad
302 pin
303 through hole
4 chip
5 sealing member
6 silicone oil
7 protective layer

### DETAILED DESCRIPTION

Technical solutions of embodiments of the present application will be described below with reference to the drawings.

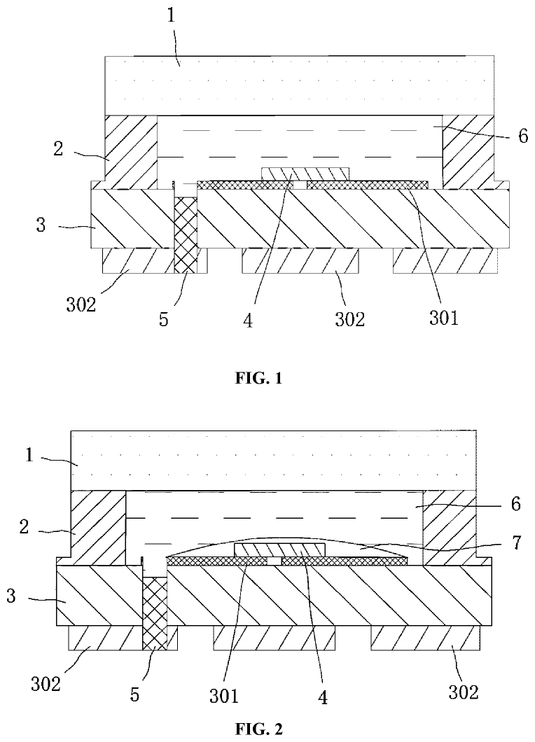

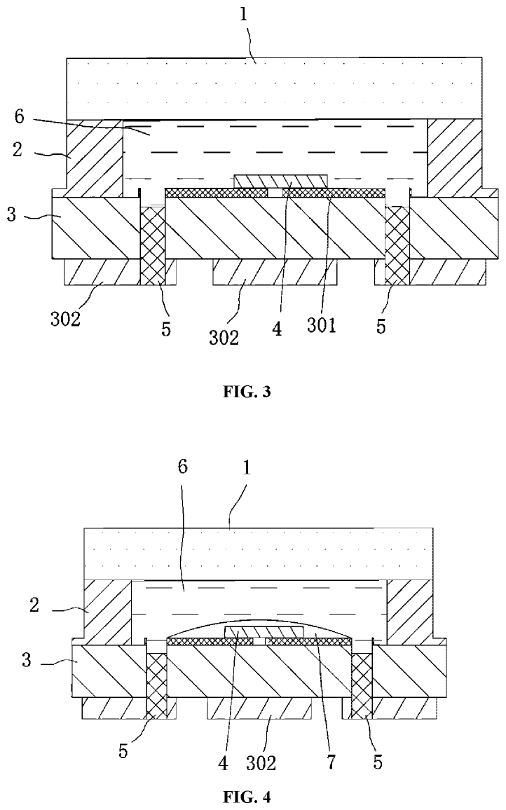

As shown in FIGS. 1, 3 and 5, the present application provides an ultraviolet LED device (which is referred to as the LED device hereinafter). The LED device includes a holder and a lens 1. The holder is provided with an accommodation cavity. The lens 1 seals the accommodation cavity. A chip is disposed at a cavity bottom of the accommodation cavity. The accommodation cavity is further filled with a Si—O main chain polymer. The holder is provided with at least one through hole 303. The at least one through hole 303 is located at the bottom of the holder and communicates with the accommodation cavity. The at least one through hole 303 and the chip 4 are spaced apart. A sealing member 5 is disposed in each through hole 303. The accommodation cavity is filled with the Si—O main chain polymer so that the refractive index of light can be improved, thereby improving the light output efficiency of the LED device. The Si—O main chain polymer has stable performances, so the disposition of the Si—O main chain polymer does not affect other structures of the LED device so that the stability of the LED device can be ensured. The Si—O main chain polymer has a relatively good radiation resistance and thereby can still maintain its molecular structure under the long-term irradiation of ultraviolet, so the LED device filled with the Si—O main chain polymer has a relatively long service life.

In this embodiment, the Si—O main chain polymer is silicone oil 6. Silicone oil generally refers to a linear polysiloxane product that remains in a liquid state at room temperature, which is generally divided into two types: methyl silicone oil and modified silicone oil. The methyl silicone oil is also referred to as common silicone oil, and all its organic groups are methyl. The methyl silicone oil has good chemical stability, insulation and good hydrophobicity. The silicone oil is a colorless (or faint-yellow), odorless, non-toxic and non-volatile liquid. The silicone oil is insoluble in water, methanol, ethylene glycol and 2-ethoxyethanol and may be mutually soluble in benzene, dimethyl ether, methyl ethyl ketone, carbon tetrachloride or kerosene and slightly soluble in acetone, dioxane, ethanol and butanol. The silicone oil has a very small vapor pressure, a relatively high flash point and ignition point and a relatively low solidifying point. The silicone oil has heat resistance, electrical insulation, weather fastness, hydrophobicity, physiological inertia and a relatively small surface tension as well as a low viscosity-temperature coefficient and a relatively high compression resistance. Some kinds of silicone oils also have radiation resistance.

Since the silicone oil 6 is a liquid substance, when a front injection is used for filling, air in the accommodation cavity cannot be completely discharged, and the surface of the silicone oil 6 is prone to forming an irregular concave surface, resulting in inconsistent light output performances of the LED device at multiple angles and reducing the light output efficiency. If the filling amount of the silicone oil 6 is added, excessive silicone oil 6 is prone to overflowing from the joint between the lens 1 and the holder, reducing the sealing performance of the LED device. Since the lens 1 has a relatively high hardness, it is relatively difficult to drill a hole at the lens 1, and the lens 1 has a relatively thin thickness, the silicone oil 6 cannot be effectively sealed. In this embodiment, the holder is provided with the at least one through hole 303 so that the silicone oil 6 can be filled to the back of the LED device. This back filling can completely discharge the air in the accommodation cavity of the holder so that the accommodation cavity can be completely filled with the silicone oil 6, thereby enabling the LED device to have a relatively good light output consistency. Moreover, the disposition of holes at the back is simple to operate and easy to achieve batch production so that the production efficiency can be effectively improved.

Referring to FIGS. 2 and 4, one side of the chip 4 facing the lens 1 is provided with a protective layer 7, and the protective layer 7 spaces the chip 4 from the silicone oil 6. The protective layer 7 and the holder jointly seal the chip 4. When filling with the silicone oil 6 is completed, the protective layer 7 can reduce the impact of the flowing silicone oil 6 on the chip 4 so that the reliability of the chip 4 can be improved. After filling with the silicone oil 6 is completed, the protective layer 7 can prevent impurities such as moisture from penetrating into the chip 4 so that the normal operation of the LED device can be ensured.

In this embodiment, the protective layer 7 is made of fluororesin or may also be made of another fluoride. Fluororesin is a kind of thermoplastic resin containing fluorine atoms in its molecular structure and has an excellent high and low temperature resistance, dielectric property, chemical stability, weather fastness, incombustibility, non-stickiness and low friction coefficient. Main varieties of fluororesins are polytetrafluoroethylene (PTFE), polytrifluorochloroethylene (PCTFE), polyvinylidene fluoride (PVDF), ethylene tetrafluoroethylene (ETFE), ethylenechlorotrifluoroethylene (ECTFE) and polyvinyl fluoride (PVF).

After being hardened, the fluororesin has a relatively good high-temperature resistance, and both the fluororesin and the silicone oil 6 have a relatively good ultraviolet resistance and stable chemical properties. The disposition of the protective layer 7 made of the fluororesin can improve the light output efficiency of the LED device by 10% to 15%. Therefore, the disposition of the protective layer 7 made of the fluororesin and the silicone oil 6 can improve the light output efficiency of the LED device.

One side of the protective layer 7 facing the lens 1 is a cambered surface, and the cambered surface of the protective layer 7 protrudes towards one side of the lens 1. The side of the protective layer 7 facing the lens 1 may also be a spherical surface, and the spherical surface of the protective layer 7 correspondingly protrudes towards the side of the lens 1. The protective layer 7 having a cambered surface or spherical surface may serve as a convex lens, so the protective layer 7 can refract the light emitted from the chip 4 so that the light output efficiency of the LED device can be improved.

The sealing member 5 is disposed in the each through hole 303 and includes a metal material. The sealing member 5 including the metal material has a good heat conductivity. The heat conduction coefficient of the sealing member 5 is greater than the heat conductive coefficient of the holder. During use, heat of the chip 4 may be transmitted to the sealing member from the holder. This can improve the heat dissipation effect of the LED device.

In this embodiment, the sealing member 5 is a silver paste member. Silver paste is a viscous slurry of a mechanical mixture composed of fine particles of metal silver having a high purity (99.9%), an adhesive, a solvent and an auxiliary agent. The sealing member 5 made of the silver paste has a good heat conductivity, and the heat produced by the chip 4 may be transmitted to the sealing member 5 by the holder so that the heat dissipation of the LED device can be facilitated, and the service life of the LED device can be prolonged.

The sealing member 5 needs to have stable chemical properties and the ability to be quickly solidified at a high temperature. Meanwhile, the sealing member 5 cannot chemically react with the silicone oil 6, so the sealing member 5 may also be made of resin.

In this embodiment, the holder includes a substrate 3 and an annular box dam 2, the lens 1 is connected to the box dam 2, the accommodation cavity is formed between the substrate 3, the box dam 2 and the lens 1, the chip 4 is secured on the substrate 3, the at least one through hole 303 is disposed on the substrate 3, the surface of one side of the substrate 3 facing away from the accommodation cavity is provided with pins 302, and the surface of one side of the substrate 3 facing the accommodation cavity is provided with pads 301.

In this embodiment, the thermal expansion coefficient of the substrate 3 is (2.0−6.0)×10⁻⁶/K, and the thermal expansion coefficient of the sealing member 5 needs to be greater than the thermal expansion coefficient of the substrate 3 to ensure that the sealing member 5 can be firmly secured to the each through hole 303 during the use of the LED device and ensure the sealing of the LED device. For example, the thermal expansion coefficient of the sealing member 5 is (30−200)×10⁻⁶/K.

The at least one through hole 303 and the protective layer 7 are spaced apart so that the effect on the structure of the protective layer 7 can be reduced, and the protective effect of the protective layer 7 on the chip 4 can be ensured.

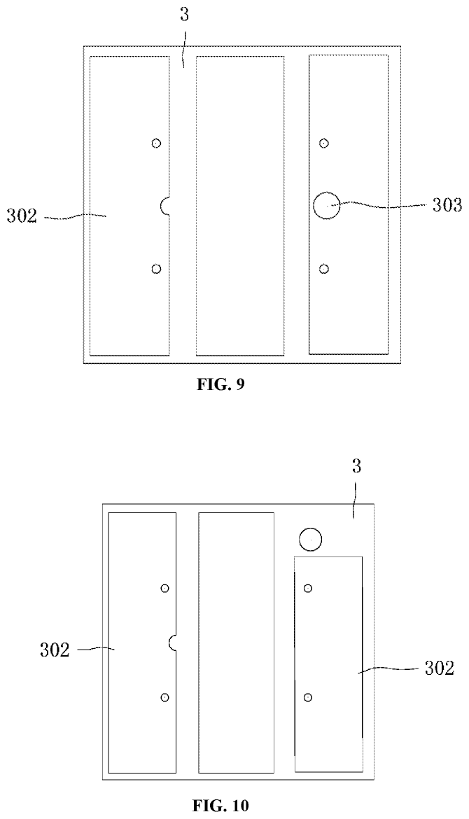

In an embodiment, referring to FIGS. 8 and 9, the through hole 303 penetrates through the pin 302. Since the sealing member is the silver paste member, the sealing member configured to seal the each through hole 303 may contact the respective pin 302, and the heat produced by the chip 4 may be quickly transmitted to the respective pin 302 so that the heat dissipation performance of the LED device can be improved. After the machining of the LED device is completed, the pins 302 on the substrate 3 need to be soldered onto an external circuit. During soldering, a solder paste is generally used as the flux. The each through hole 303 is disposed on the respective pin 302, and the solder paste may seal the each through hole 303 for the second time during soldering so that the air tightness of the LED device can be ensured.

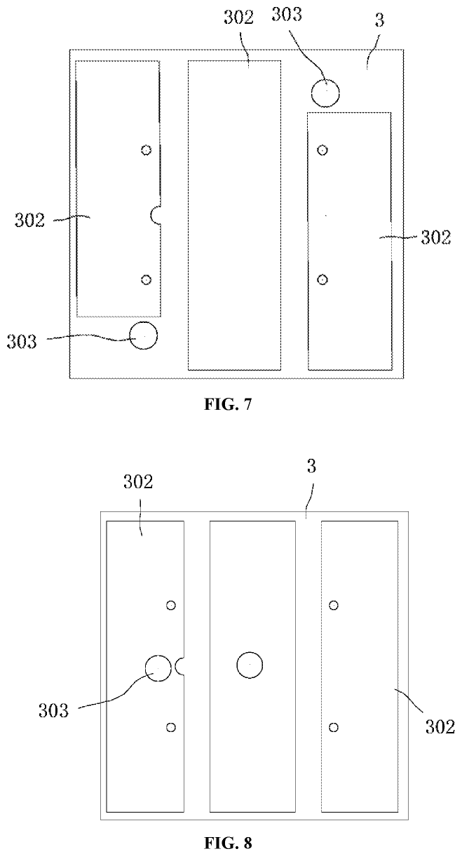

In another embodiment, the lens 1 is made of quartz glass, the substrate 3 is made of ceramics, and the external surface of the substrate 3 needs to be provided with a metal layer. Referring to FIGS. 7 and 10, the each through hole 303 is disposed outside the respective pin 302. When the substrate 3 is machined, the substrate 3 may be first drilled to form the at least one through hole 303, and then the substrate 3 is plated with metal to form the metal layer. Compared with the structure in which the through hole 303 penetrates through the pin 302, the each through hole 303 is disposed outside the respective pin 302 so that the machining process difficulty of the substrate 3 can be lowered, the machining efficiency of the substrate 3 can be improved, and the batch production of substrates 3 can be facilitated.

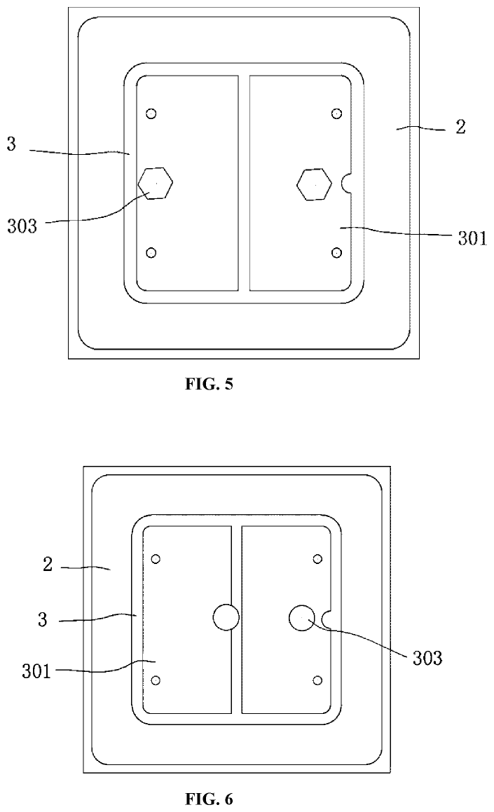

Referring to FIGS. 9 and 10, in an embodiment, the substrate 3 is provided with one through hole 303. Referring to FIGS. 5 to 8, in another embodiment, the substrate 3 is provided with two through holes 303. The distance between the two through holes 303 may be designed according to the size of the LED device. The disposition positions of the two through holes 3 are selected according to the requirements of the LED device. In this embodiment, the substrate 3 is provided with three pins 302 and two pads 301, and the each through hole 3 may selectively penetrate through any pad 301 or pin 302.

Referring to FIG. 7, in this embodiment, the substrate 3 is quadrangular, and the two through holes 303 are respectively located in two opposite corner regions of the substrate 3, and the two through holes 303 are each spaced from the two pins 302. This can directly perform drilling on the substrate 3 to lower the machining difficulty of the two through holes 303, and the diameter of each through hole 303 may be designed according to the actual requirements of the LED device. In addition, the two through holes 303 are respectively disposed in the two opposite corner regions of the substrate 3 and outside the two pins 302 so that the effect of the two through holes 303 on patches of the LED device can be reduced.

When the through hole 303 penetrates through the pad 301, the diameter of the each through hole 303 is ¼ to ½ of the width of the respective pad 301. This can ensure that the respective pad 301 can have sufficient area to be soldered onto the chip 4. In this embodiment, the diameter of the each through hole 303 is 0.3 mm. Referring to FIGS. 5 and 6, the shape of the cross-section of the each through hole 303 may be designed according to the requirements of the product. For example, the cross-section of the each through hole 303 may be circular, triangular or another polygon. In this embodiment, the cross-section of the each through-hole 303 is circular so that the machining difficulty of the each through-hole 303 can be lowered, and the machining efficiency of the substrate 3 can be improved.

The present application further provides a method for preparing an ultraviolet LED device for preparing the preceding LED device. The method includes the steps below.

The bottom of the holder is machined through a drilling tool to form the at least one through hole 303, where the at least one through hole 303 communicates with the accommodation cavity on the holder; the chip 4 is soldered onto the cavity bottom of the accommodation cavity; the lens 1 is secured on the soldered holder, where the lens 1 is configured to seal the accommodation cavity; the secured holder is inverted to enable the at least one through hole 303 to face upward, and the accommodation cavity is filled with the Si—O main chain polymer through the at least one through hole 303; and the each through hole 303 is sealed by the sealing member 5 after filling with the Si—O main chain polymer is completed.

The substrate 3 of the holder is first machined by the drilling tool to form the at least one through hole 303, then the chip 4 and the substrate 3 are soldered, the soldered holder and the lens 1 are secured, the secured holder is inverted to enable the at least one through hole 303 to face upward, the accommodation cavity is filled with the silicone oil 6 through the at least one through hole 303, and the each through hole 303 is sealed by the sealing member 5 after filling with the silicone oil 6 is completed.

The drilling process is disposed before the soldering process of the chip 4. This can not only lower the formation difficulty of the at least one through hole 303, but also prevent the drilling operation from affecting the connection stability between the chip 4 and the substrate 3. The inverted holder is filled with the silicone oil 6 so that the filling difficulty can be lowered. When filling with the silicone oil 6 is completed, the at least one through hole 303 faces upward so that the discharge of the air in the accommodation cavity can be facilitated.

The substrate 3 is provided with the two through holes 303. The accommodation cavity is filled with the silicone oil 6 by one through hole 303 while the other through hole 303 is used as an air outlet. When the silicone oil 6 overflows or is about to overflow from the other through hole 303 which is used as the air outlet, filling of the silicone oil 6 is stopped, and the two through holes 303 are respectively sealed by two sealing members 5. The other through hole 303 is disposed as the air outlet so that the discharge of the air in the accommodation cavity can be facilitated during the filling operation, the silicone oil 6 can fill the accommodation cavity, and the light output efficiency can be improved. Secondly, the disposition of the two through holes 303 facilitates the flow of liquid and air in the accommodation cavity in a particular direction and facilitates the improvement in the filling efficiency of the accommodation cavity.

The diameters of the two through holes 303 may be different. The diameter of the through hole 303 configured to be filled with the silicone oil 6 may be greater than the diameter of the other through hole 303 which is used as the air outlet. This can lower the filling difficulty of the silicone oil 6 and improve the efficiency of the filling operation.

After the chip 4 and the substrate 3 are soldered and before the holder and the lens 1 are secured, the protective layer 7 is coated on the surface of the chip 4. Since the protective layer 7 has the protective effect on the chip 4, the protective layer 7 needs to completely cover the chip 4. Therefore, the coating operation is performed before the holder and the lens 1 are secured so that the operation difficulty of the coating operation can be lowered, and the formation of the protective layer 7 can be facilitated.

The steps of securing the holder and the lens 1 include the following.

The surface of one side of the box dam 2 of the holder facing away from the substrate 3 is applied with encapsulant, and the lens 1 and the box dam 2 are fitted.

In this embodiment, that the sealing member 5 is the silver paste member, and the each through hole 303 is sealed by the sealing member 5 includes the step below.

The each through hole 303 is filled with silver paste, and after filling with the silver paste is completed, a high-temperature treatment is performed on the each through hole 303 to harden the silver paste to form the silver paste member.

The liquid silver paste is hardened at a high temperature in the each through hole 303 to form the silver paste member so that the sealing effect of the sealing member 5 on the LED device can be ensured, thereby prolonging the service life of the LED device.

In this embodiment, the each through hole 303 is also filled with the silicone oil 6. This can facilitate the complete discharge of the air in the accommodation cavity and prevent the light output efficiency of the LED device from being affected by an irregular concave surface formed on the surface of the silicone oil 6 due to air residue in the accommodation cavity. When the each through hole 303 is filled with excessive silicone oil 6, the volume of the sealing member 5 is reduced. This not only reduces the heat dissipation performance of the LED device, not helping to dissipate the heat of the chip 4, but also reduces the sealing effect of the LED device. Therefore, the filling depth of the silicone oil 6 in the each through hole 303 is ⅕ to ¼ of the depth of the each through hole 303.

What is claimed is:

1. An ultraviolet LED device, comprising a holder and a lens, wherein the holder is provided with an accommodation cavity, the lens is configured to seal the accommodation cavity, and a chip is disposed at a cavity bottom of the accommodation cavity, wherein the accommodation cavity is filled with a silicon-oxygen main chain polymer, the holder is provided with at least one through hole, the at least one through hole is located at a bottom of the holder and communicates with the accommodation cavity, and the at least one through hole and the chip are spaced apart, and a sealing member is disposed in each of the at least one through hole.

2. The ultraviolet LED device according to claim 1, wherein two through holes are spaced apart at the bottom of the holder.

3. The ultraviolet LED device according to claim 2, wherein the sealing member comprises a metal material, or the sealing member is made of resin.

4. The ultraviolet LED device according to claim 3, wherein the sealing member is a silver paste member.

5. The ultraviolet LED device according to claim 1, wherein one side of the chip facing the lens is provided with a protective layer, and the protective layer is configured to isolate the chip from the silicon-oxygen main chain polymer.

6. The ultraviolet LED device according to claim 5, wherein the protective layer is made of fluororesin.

7. The ultraviolet LED device according to claim 5, wherein one side of the protective layer facing the lens is a cambered surface or spherical surface, and the cambered surface or spherical surface protrudes towards one side of the lens.

8. The ultraviolet LED device according to claim 5, wherein the at least one through hole and the protective layer are spaced apart.

9. The ultraviolet LED device according to claim 1, wherein the holder comprises a substrate and an annular box dam, the lens is connected to the box dam, the accommodation cavity is formed between the substrate, the box dam and the lens, the chip is secured on the substrate, a surface of one side of the substrate facing away from the accommodation cavity is provided with pins, the at least one through hole is disposed on the substrate, and the at least one through hole penetrates through the pins.

10. The ultraviolet LED device according to claim 1, wherein the holder comprises a substrate and an annular box dam, the lens is connected to the box dam, the accommodation cavity is formed between the substrate, the box dam and the lens, the chip is secured on the substrate, the at least one through hole is disposed on the substrate, a surface of one side of the substrate facing away from the accommodation cavity is provided with pins, and the at least one through hole and the pins are spaced apart.

11. A method for preparing an ultraviolet LED device, wherein the ultraviolet LED device comprises a holder and a lens, wherein the holder is provided with an accommodation cavity, the lens is configured to seal the accommodation cavity, and a chip is disposed at a cavity bottom of the accommodation cavity, wherein the accommodation cavity is filled with a silicon-oxygen main chain polymer, the holder is provided with at least one through hole, the at least one through hole is located at a bottom of the holder and communicates with the accommodation cavity, and the at least one through hole and the chip are spaced apart, and a sealing member is disposed in each of the at least one through hole;
the method comprises:
machining the bottom of the holder through a drilling tool to form the at least one through hole, wherein the at least one through hole communicates with the accommodation cavity on the holder;
soldering the chip onto the cavity bottom of the accommodation cavity;
securing the lens on a soldered holder, wherein the lens is configured to seal the accommodation cavity;
inverting a secured holder to enable the at least one through hole to face upward, and filling the accommodation cavity with the silicon-oxygen main chain polymer through the at least one through hole; and
sealing the each of the at least one through hole with the sealing member after filling with the silicon-oxygen main chain polymer is completed.

12. The method for preparing an ultraviolet LED device according to claim 11, before securing the lens on the soldered holder, the method further comprising:
coating a protective layer on a surface of the chip.

13. The method for preparing an ultraviolet LED device according to claim 11, wherein the sealing member is a silver paste member, and sealing the each of the at least one through hole with the sealing member comprises:
filling the each of the at least one through hole with silver paste, and performing, after filling with silver paste is completed, a high-temperature treatment on the each of the at least one through hole to harden the silver paste to form the silver paste member.

14. The method for preparing an ultraviolet LED device according to claim 11, wherein two through holes are disposed at the bottom of the holder;
wherein filling the accommodation cavity with the silicon-oxygen main chain polymer through the at least one through hole comprises:
filling the accommodation cavity with the silicon-oxygen main chain polymer through one of the two through holes, using another one of the two through holes as an air outlet;
wherein sealing the each of the at least one through hole with the sealing member after filling with the silicon-oxygen main chain polymer is completed comprises:
in a case where the silicon-oxygen main chain polymer overflows or is about to overflow from the another one of the two through holes which is used as the air outlet, stopping filling with the silicon-oxygen main chain polymer and sealing the two through holes with two sealing members.

15. The method for preparing an ultraviolet LED device according to claim 11, wherein two through holes are spaced apart at the bottom of the holder.

16. The method for preparing an ultraviolet LED device according to claim 11, wherein one side of the chip facing the lens is provided with a protective layer, and the protective layer is configured to isolate the chip from the silicon-oxygen main chain polymer.

17. The method for preparing an ultraviolet LED device according to claim 16, wherein one side of the protective layer facing the lens is a cambered surface or spherical surface, and the cambered surface or spherical surface protrudes towards one side of the lens.

18. The method for preparing an ultraviolet LED device according to claim 16, wherein the at least one through hole and the protective layer are spaced apart.

19. The method for preparing an ultraviolet LED device according to claim 11, wherein the holder comprises a substrate and an annular box dam, the lens is connected to the box dam, the accommodation cavity is formed between the substrate, the box dam and the lens, the chip is secured on the substrate, a surface of one side of the substrate facing away from the accommodation cavity is provided with pins, the at least one through hole is disposed on the substrate, and the at least one through hole penetrates through the pins.

20. The method for preparing an ultraviolet LED device according to claim 11, wherein the holder comprises a substrate and an annular box dam, the lens is connected to the box dam, the accommodation cavity is formed between the substrate, the box dam and the lens, the chip is secured on the substrate, the at least one through hole is disposed on the substrate, a surface of one side of the substrate facing away from the accommodation cavity is provided with pins, and the at least one through hole and the pins are spaced apart.
